(19) United States
(12) Patent Application Publication
(10) Pub. No.: US 2018/0103565 A1
(43) Pub. Date: Apr. 12, 2018

(54) DISPLAY DEVICE

(71) Applicant: Panasonic Liquid Crystal Display Co., Ltd., Himeji-shi (JP)

(72) Inventor: Tomohiro MAEYAMA, Kanagawa (JP)

(21) Appl. No.: 15/836,192

(22) Filed: Dec. 8, 2017

Related U.S. Application Data
(62) Division of application No. 15/085,690, filed on Mar. 30, 2016.

(51) Int. Cl. H05K 9/00; H05K 1/02; G02F 1/133; G02F 1/1335; G02F 1/1368; H04B 1/3827

(52) U.S. Cl. CPC H05K 9/0084; H05K 2201/10136; G02F 2202/28; H05K 1/028; H05K 1/0216; G02F 1/133528; G02F 1/13306; G02F 1/133514; G02F 1/1368; H04B 1/3827

(57) ABSTRACT

A display device includes a TFT substrate including an overlap portion overlapping the color filter substrate and a non-overlap portion which does not overlap the color filter substrate; a color filter substrate; a source driver; and a height adjusting body. A color filter surface of the color filter substrate is opposite a surface facing a first major surface of the TFT substrate at a first distance. The source driver is disposed on the non-overlap portion and has a source driver surface that is opposite a surface facing the first major surface and disposed a second distance from the first major surface, which is less than the first distance. The height adjusting body is disposed on the non-overlap portion and has a height adjusting body surface opposite a surface facing the first major surface disposed a third distance from the first major surface, which is greater than the second distance.

### FIELD

This disclosure relates generally to a display device. More specifically, the disclosure relates to a display device such as, but not limited to, a liquid crystal display device including an electromagnetic interference (EMI) shielding layer.

### BACKGROUND

A liquid crystal display (LCD) device is an electronic display that is widely used as a display for electronic devices such as computers, televisions, cellular phones, and the like. LCD devices generally include a thin film transistor (TFT) substrate and a color filter substrate. A liquid crystal layer is disposed between the TFT substrate and the color filter substrate.

### SUMMARY

This disclosure relates generally to a display device. More specifically, the disclosure relates to a display device such as, but not limited to, a liquid crystal display device, having an electromagnetic interference (EMI) shielding layer.

In an embodiment, a display device is a liquid crystal display device.

In an embodiment, the liquid crystal display device is an in-plane switching (IPS) mode liquid crystal display device.

In an embodiment, the display device is included as a display for an electronic device such as, but not limited to, a display for a laptop computer, a display for a tablet computer, a display for a desktop computer, or the like.

In an embodiment, the EMI shielding layer is an EMI shielding tape.

In an embodiment, a height adjusting body compensates for a difference in height for a color filter substrate and a source driver in the display device. The height adjusting body can be thermally conductive and electrically insulative. In an embodiment, the height adjusting body can be relatively compressible. In an embodiment, the height adjusting body can be relatively incompressible. Suitable materials for the height adjusting body include, but are not limited to, a rubber, a thermoplastic polymer resin such as polyethylene terephthalate (PET), polypropylene, or the like.

A display device is disclosed. The display device includes a thin film transistor (TFT) substrate having first and second major surfaces; a color filter substrate opposed to the first major surface of the TFT substrate. The TFT substrate includes an overlap portion which overlaps the color filter substrate and a non-overlap portion which does not overlap the color filter substrate. A color filter surface of the color filter substrate that is opposite a surface facing the first major surface is disposed a first distance from the first major surface. A source driver is disposed on the non-overlapping portion of the TFT substrate. A source driver surface of the source driver that is opposite a surface facing the first major surface is disposed a second distance from the first major surface, and the second distance is less than the first distance. The display device further includes a height adjusting body disposed on the non-overlapping portion of the TFT substrate. A height adjusting body surface of the height adjusting body that is opposite a surface facing the first major surface is disposed a third distance from the first major surface. The third distance is greater than the second distance.

### BRIEF DESCRIPTION OF THE DRAWINGS

References are made to the accompanying drawings that form a part of this disclosure and which illustrate embodiments in which the systems and methods described in this specification can be practiced.

FIG. 1 illustrates a plan view of a display device, according to an embodiment.

FIG. 2 illustrates a side sectional view of the display device of FIG. 1, according to an embodiment.

FIG. 3 illustrates a side sectional view of the display device of FIG. 1, according to another embodiment.

FIGS. 4A-4C illustrate side sectional views of the display device of FIG. 1, according to some embodiments.

Like reference numbers represent like parts throughout.

### DETAILED DESCRIPTION

A display device generally includes a flexible printed circuit, a printed circuit board (PCB), and a plurality of source drivers. The flexible printed circuit, PCB, and source drivers are covered by an electromagnetic interference (EMI) shielding tape. The EMI shielding tape serves multiple functions such as, but not limited to, protecting the flexible printed circuit, PCB, and source drivers from electromagnetic interference, as well as selectively electrically connecting particular components of the flexible printed circuit (e.g., to a ground terminal, etc.), PCB, and source drivers.

In an embodiment, a variation in height between the various components being covered by the EMI shielding tape may lead to stress concentrations that can cause the EMI shielding tape to be disconnected from the various components. Disconnection of the EMI shielding tape from the various components can adversely impact the electrical connections between the various components. In some cases, the stress concentrations can lead to tearing of the EMI shielding tape.

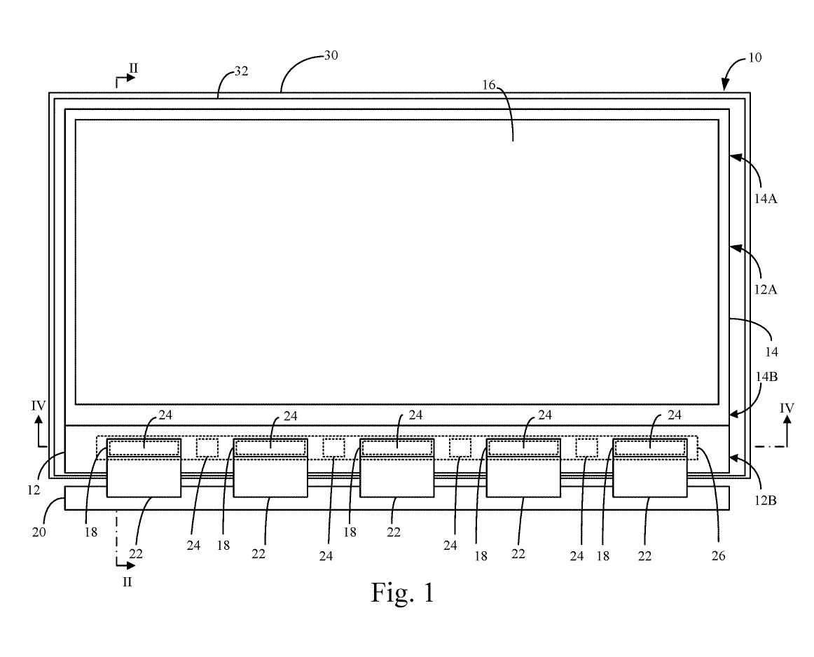

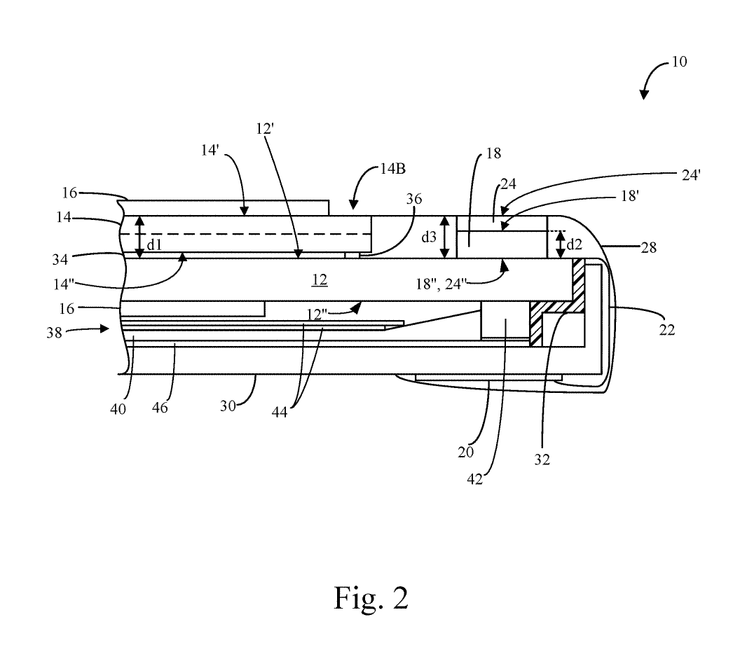

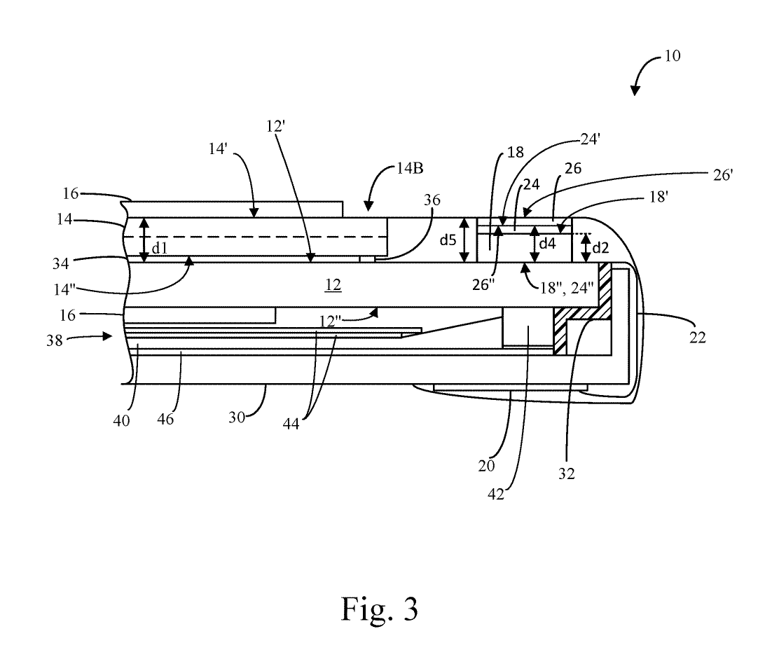

FIG. 1 illustrates a plan view of a display device 10, according to an embodiment. The display device 10 generally includes a thin film transistor (TFT) substrate 12, a color filter substrate 14, a polarizer 16, a plurality of source drivers 18, a PCB 20, and one or more connectors 22. It will be appreciated that the display device 10 can include one or more additional features. For example, the display device 10 can include a liquid crystal layer (e.g., liquid crystal layer 34 shown and described with reference to FIGS. 2-3) sandwiched between the TFT substrate 12 and the color filter substrate 14. A metal frame 30 is disposed around a perimeter of the TFT substrate 12, according to an embodiment. A resin frame 32 is positioned around a light source (e.g., light source 42 shown and described in accordance with FIGS. 2-3). One or more tabs or other portions may extend outwardly from the metal frame 30 to provide, for example, a location at which the display device 10 can be fixed into an electronic device.

The TFT substrate 12 is relatively larger than the color filter substrate 14. The TFT substrate 12 includes an overlap portion 12A and a non-overlap portion 12B. In the overlap portion 12A, the TFT substrate 12 overlaps the color filter substrate 14. In the non-overlap portion 12B, the TFT substrate 12 does not overlap the color filter substrate 14.

The color filter substrate 14 is relatively larger than the polarizer 16. The color filter substrate 14 includes an overlap portion 14A and a non-overlap portion 14B. In the overlap portion 14A, the color filter substrate 14 overlaps the polarizer 16. In the non-overlap portion 14B, the color filter substrate 14 does not overlap the polarizer 16.

The plurality of source drivers 18 is disposed in the non-overlap portion 12B of the TFT substrate 12. As can be seen in FIG. 1, there is a gap between the color filter substrate 14 and the plurality of source drivers 18. The plurality of source drivers 18 are electrically connected to the PCB 20 via the one or more connectors 22. In an embodiment, the one or more connectors 22 can alternatively be referred to as the one or more flexible connectors 22, the one or more flexible printed circuits 22, or the like. In an embodiment, the one or more connectors 22 can alternatively be a single flexible connector 22 that extends between the plurality of source drivers 18. It will be appreciated that in some display devices, the PCB 20 may alternatively be disposed on an opposite side of the TFT substrate 12 from the plurality of source drivers 18. In such an embodiment, the one or more connectors 22 wrap around an edge of the TFT substrate 12 (see, e.g., FIGS. 2-3 below). In the illustrated embodiment, a gap is shown between the TFT substrate 12 and the PCB 20. It is to be appreciated that in an embodiment there may be no gap between the TFT substrate 12 and the PCB 20.

An EMI shielding layer (e.g., EMI shielding layer 28 as shown and discussed with respect to FIGS. 2-3 below) can be connected to a surface of the color filter substrate 14 in the non-overlap portion 14B.

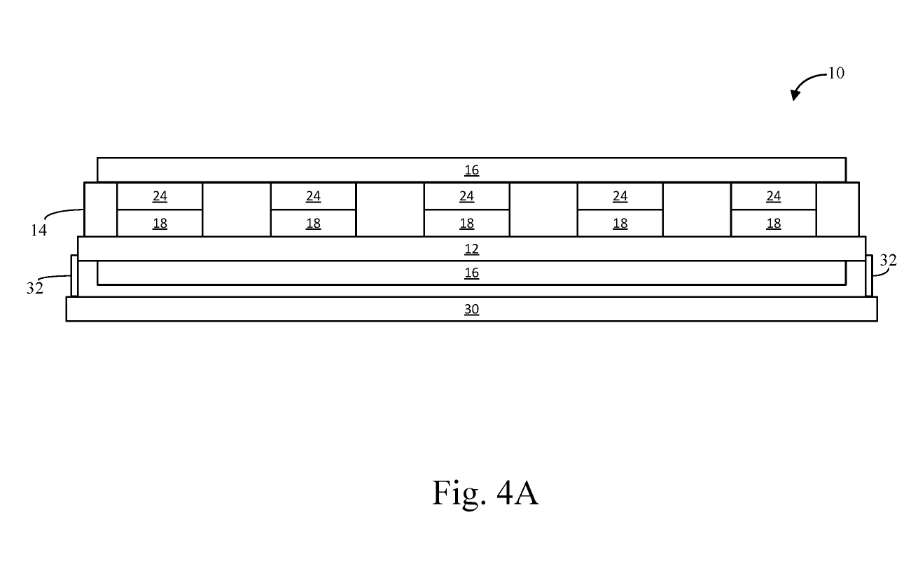

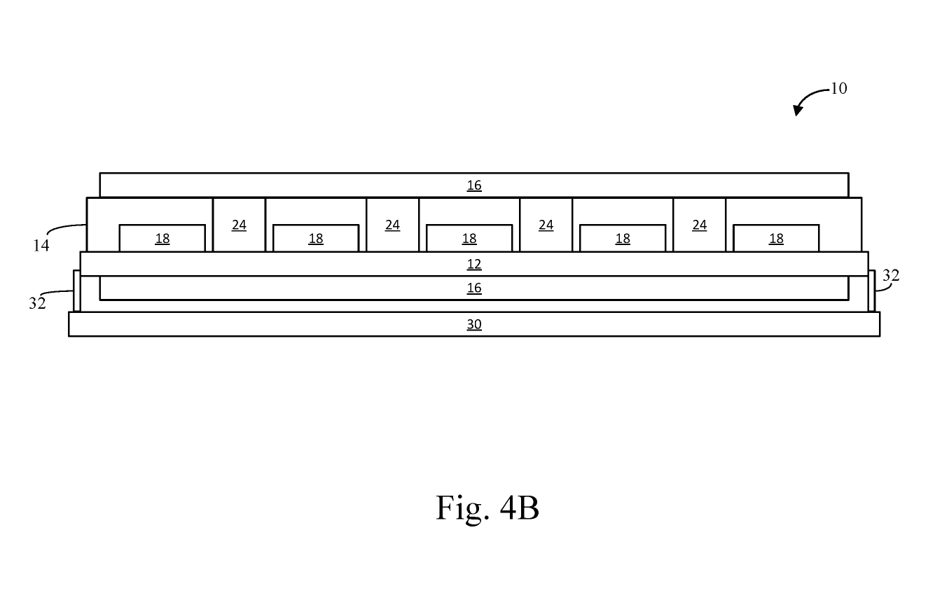

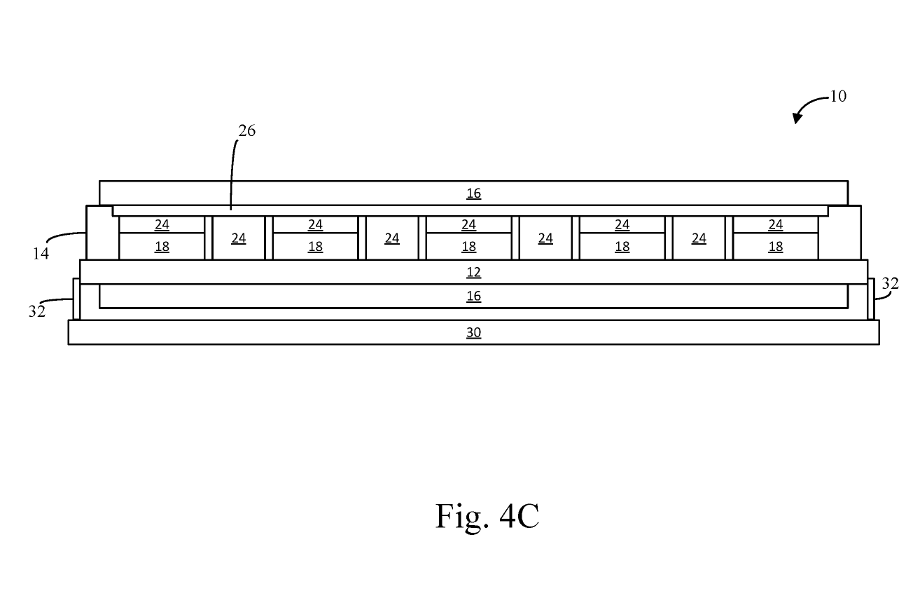

A plurality of height adjusting bodies 24 are shown in FIG. 1. The plurality of height adjusting bodies 24, illustrated in dashed lines, may be included in the display device 10 at various locations. The various locations corresponding to the plurality of height adjusting bodies 24 are shown and described in additional detail in accordance with FIGS. 2-4C below. It will be appreciated that the plurality of height adjusting bodies 24 can be included with the display device 10 in accordance with FIG. 2, in accordance with FIG. 3, or in accordance with a combination of FIGS. 2 and 3. Alternative views of the various locations of the height adjusting bodies 24 are shown and described in additional detail in accordance with FIGS. 4A-4C below.

A connecting member 26 is shown in FIG. 1. The connecting member 26, illustrated in dashed lines, may be included in the display device 10. The connecting member 26 may be disposed between the plurality of height adjusting bodies 24 and the EMI shielding layer. The connecting member 26 is shown and described in additional detail in accordance with FIG. 3 below.

FIG. 2 illustrates a side view along line II-II of a portion of the display device 10, according to an embodiment. For simplicity of this specification, aspects which have been previously described with respect to FIG. 1 will not be re-described with reference to FIG. 2.

In addition to the aspects of the display device 10 described in FIG. 1, the display device 10 includes an EMI shielding layer 28. As discussed above with respect to FIG. 1, the PCB 20 is illustrated on an opposite side of the TFT substrate 12 from the view shown in FIG. 1.

The TFT substrate 12 includes a first major surface 12′ and a second major surface 12″. A first surface 14′ of the color filter substrate 14 is opposite a second surface 14″ of the color filter substrate 14. The second surface 14″ of the color filter substrate 14 faces the first major surface 12′ of the TFT substrate 12. A liquid crystal layer 34 is disposed between the first major surface 12′ of the TFT substrate 12 and the second surface 14″ of the color filter substrate 14. A seal 36 fixes the TFT substrate 12 and the color filter substrate 14. In an embodiment, the seal 36 can be made of, for example, a resin or the like. The first surface 14′ is disposed a distance d1 from the first major surface 12′. The distance d1 can vary. A second polarizer 16 is disposed on the second major surface 12″ of the TFT substrate 12. The first and second surfaces 14′, 14″ can alternatively be referred to as color filter surfaces of the color filter 14.

It will be appreciated that the display device 10 can include one or more intervening layers disposed between the first surface 14′ and the second surface 14″ of the color filter substrate 14. For example, in an embodiment the color filter substrate 14 can include a plurality of layers, as represented by the dashed line in FIG. 2.

A first surface 18′ of each of the plurality of source drivers 18 is opposite a second surface 18″ of each of the plurality of source drivers 18. The second surface 18″ of each of the plurality of source drivers 18 faces the first major surface 12′ of the TFT substrate 12. The first surface 18′ of each of the plurality of source drivers 18 is a distance d2 from the first major surface 12′. The distance d2 can vary. In general, the distance d2 is less than the distance d1. In prior display devices 10, the variation between the distance d1 and the distance d2 can lead to an increase in stress concentrations which can cause the EMI shielding layer 28 to be disconnected from the color filter substrate 14 and/or can lead to tears in the EMI shielding layer 28. The first and second surfaces 18′, 18″ can alternatively be referred to as source driver surfaces of the source drivers 18.

In the illustrated embodiment, the plurality of height adjusting bodies 24 can be included to compensate for the difference between the distance d1 and the distance d2. Each of the plurality of height adjusting bodies 24 includes a first surface 24′ that is opposite a second surface 24″. The second surface 24″ of each of the plurality of height adjusting bodies 24 faces the first major surface 12′ of the TFT substrate 12. The first surface 24′ of each of the plurality of height adjusting bodies 24 is disposed a distance d3 from the first major surface 12′ of the TFT substrate 12. In an embodiment, the distance d3 can be about the same as the distance d1. In an embodiment, the distance d3 can be about the same as or less than the distance d1. The first and second surfaces 24′, 24″ can alternatively be referred to as height adjusting body surfaces of the height adjusting bodies 24.

In an embodiment, the plurality of height adjusting bodies 24 can be disposed on the first surface 18′ of the plurality of source drivers 18. In an embodiment, the plurality of height adjusting bodies 24 can be disposed on the first major surface 12′ in the non-overlap portion 12B of the TFT substrate 12 (see FIG. 1). In such an embodiment, the plurality of height adjusting bodies 24 can be disposed between the plurality of source drivers 18. In an embodiment, the plurality of height adjusting bodies 24 can be disposed on the non-overlap portion 12B between the plurality of source drivers 18 and the color filter substrate 14 (see FIG. 1). It will be appreciated that the plurality of height adjusting bodies 24 can be disposed in a combination of these locations. For example, in an embodiment, a first of the plurality of height adjusting bodies 24 can be disposed on the first surface 18′ of a first of the plurality of source drivers 18 and a second of the plurality of height adjusting bodies 24 can be disposed on the first major surface 12′ of the TFT substrate 12.

The plurality of height adjusting bodies 24 can be made of a variety of materials. Suitable materials for the plurality of height adjusting bodies 24 include, but are not limited to, materials that are thermally conductive and electrically insulative. In an embodiment, the thermally conductive and electrically insulative material can be relatively compressible. In an embodiment, the thermally conductive and electrically insulative material can be relatively incompressible. Suitable materials for the plurality of height adjusting bodies 24 include, but are not limited to, a rubber, a thermoplastic polymer resin such as polyethylene terephthalate (PET), polypropylene, or the like.

The EMI shielding layer 28 is connected to the color filter substrate 14 at the non-overlap portion 14B of the first surface 14′ of the color filter substrate 14. In an embodiment, a transparent conductive layer such as, but not limited to, an indium-tin-oxide layer or the like, can be formed on the first surface 14′ of the color filter substrate 14. In such an embodiment, the EMI shielding layer 28 can be directly connected to the transparent conductive layer. The EMI shielding layer 28 can be, for example, an EMI shielding tape having two insulating layers sandwiching a metal layer therebetween. The EMI shielding layer 28 can include an adhesive which connects the EMI shielding layer 28 to the first surface 14′ of the color filter substrate 14. The EMI shielding layer 28 can be connected to the color filter substrate 14, the height adjusting body surface 24′, and a surface of the metal frame 30. In an embodiment, the PCB 20 can include a ground terminal and a portion of the EMI shielding layer 28 which is not covered by the insulating layers (e.g., the metal layer) can be connected to the ground terminal.

The plurality of source drivers 18 are semiconductor chips. The plurality of source drivers 18 is mounted on the first major surface 12′ of the TFT substrate 12. The plurality of source drivers 18 is electrically connected to wires formed in the one or more connectors 22. A backlight module 38 is disposed behind the TFT substrate 12 (e.g., between the TFT substrate 12 and the metal frame 30). The backlight module 38 includes a light source 42, a light guide plate 40, and one or more optical films 44 such as, but not limited to, a prism sheet, a diffusion sheet, or the like. The backlight module 38 includes the resin frame 32, which is positioned around the light source 42, the light guide plate 40, and the one or more optical films 44. A reflective film 46 is disposed between the light guide plate 40 and the metal frame 30. In an embodiment, the reflective film 46 can, for example, reflect light to increase viewing angles of the display device 10, increase brightness of the display device 10 (e.g., without increasing energy input, etc.), or the like. The reflective film 46 may be part of the backlight module 38, according to an embodiment. Attachment of the one or more connectors 22 to the TFT substrate 12 can be achieved by an adhesive (not shown). An anisotropic conductive material (not shown) may also be used in order to achieve a mechanical and electrical connection.

FIG. 3 illustrates a side view along line II-II of a portion of the display device 10, according to another embodiment.

In FIG. 3, the plurality of height adjusting bodies 24 additionally include the connecting member 26. The connecting member 26 can be made of, for example, a polyethylene terephthalate (PET) or the like. In an embodiment, the connecting member 26 can include an adhesive to additionally maintain the EMI shielding layer 28 in place. In an embodiment, the connecting member 26 can be a double-sided adhesive tape.

The height adjusting body 24 includes a first surface 24′ that is opposite a second surface 24″. The second surface 24″ of the height adjusting body 24 faces the first major surface 12′ of the TFT substrate 12. In the illustrated embodiment, the first surface 24′ is disposed a distance d4 from the first major surface 12′. In an embodiment, the distance d4 can be about the same as the distance d2. In an embodiment, the distance d4 can be about the same as or greater than the distance d2. The distance d4 is less than the distance d1.

The connecting member 26 includes a first surface 26′ that is opposite a second surface 26″ which faces the first surface 24′ of the height adjusting body 24. The first surface 26′ of the connecting member 26 is disposed a distance d5 from the first major surface 12′. The distance d5 is the same as or substantially similar to the distance d3 (FIG. 2). The first and second surfaces 26′, 26″ can alternatively be referred to as connecting member surfaces of the connecting member 26.

FIGS. 4A-4C illustrate side views along line IV-IV of the display device 10 of FIG. 1, according to some embodiments. In FIGS. 4A-4C, to simplify the view the PCB 20 and the EMI shielding layer 28 (as shown and described with reference to FIGS. 2-3 above) are not shown.

FIG. 4A illustrates the display device 10 according to an embodiment in which the plurality of height adjusting bodies 24 are disposed on the plurality of source drivers 18. FIG. 4B illustrates the display device 10 according to an embodiment in which the plurality of height adjusting bodies 24 are disposed on the TFT substrate 12. In the embodiment of FIG. 4B, the plurality of height adjusting bodies 24 are disposed in between the plurality of source drivers 18. FIG. 4C illustrates the display device 10 according to an embodiment in which the plurality of height adjusting bodies 24 are disposed on the plurality of source drivers 18, between the plurality of source drivers 18, and further includes the connecting member 26. It will be appreciated that one or more of the plurality of height adjusting bodies 24 between the plurality of source drivers 18 or one or more of the plurality of height adjusting bodies 24 disposed on the plurality of source drivers 18 can be removed from the embodiment illustrated in FIG. 4C.

The terminology used in this specification is intended to describe particular embodiments and is not intended to be limiting. The terms “a,” “an,” and “the” include the plural forms as well, unless clearly indicated otherwise. The terms “comprises” and/or “comprising,” when used in this specification, specify the presence of the stated features, integers, steps, operations, elements, and/or components, but do not preclude the presence or addition of one or more other features, integers, steps, operations, elements, and/or components.

With regard to the preceding description, it is to be understood that changes may be made in detail, especially in matters of the construction materials employed and the shape, size, and arrangement of parts without departing from the scope of the present disclosure. This specification and the embodiments described are exemplary only, with the true scope and spirit of the disclosure being indicated by the claims that follow.

1-18. (canceled)

19. A display device, comprising:
a thin film transistor (TFT) substrate having first and second major surfaces;
a color filter substrate opposed to the first major surface of the TFT substrate, wherein the TFT substrate includes an overlap portion which overlaps the color filter substrate and a non-overlap portion which does not overlap the color filter substrate, a color filter surface of the color filter substrate that is opposite a surface facing the first major surface is disposed a first distance from the first major surface;
a plurality of source drivers disposed on the non-overlap portion of the TFT substrate, source driver surface of at least one of the plurality of source drivers that is opposite a surface facing the first major surface is disposed a second distance from the first major surface, the second distance is less than the first distance; and
a first height adjusting body disposed on the non-overlap portion of the TFT substrate, a first height adjusting body surface of the first height adjusting body that is opposite a surface facing the first major surface is disposed a third distance from the first major surface, the third distance is greater than the second distance, wherein the first height adjusting body is disposed between two source drivers from the plurality of source drivers.

20. The display device according to claim 19, wherein
a height of the first height adjusting body is greater than a height of the at least one of the plurality of source drivers.

21. The display device according to claim 19 further comprising:
a second height adjusting body, the second height adjusting body being disposed on the non-overlap portion of the TFT substrate, wherein
a second height adjusting body surface of the second height adjusting body that is opposite a surface facing the first major surface is disposed the third distance from the first major surface.

22. The display device according to claim 21 further comprising:
a connecting member, wherein
the connecting member is disposed on both of the first height adjusting body surface of the first height adjusting body and the second height adjusting body surface of the second height adjusting body.

23. The display device according to claim 19, further comprising:
a metal frame connected to the TFT substrate; and
an electromagnetic interference shielding tape connected to the color filter surface, connected to the height adjusting body surface, and connected to the metal frame.

24. The display device according to claim 23, further comprising:
a polarizer, wherein
the color filter substrate includes an overlap portion which overlaps the polarizer and a non-overlap portion which does not overlap the polarizer, the polarizer being disposed on the color filter surface, and
the electromagnetic interference shielding tape is connected to the color filter surface in the non-overlap portion which does not overlap the polarizer.

25. The display device according to claim 23, further comprising:
a transparent conductive layer formed on the color filter surface, wherein
the electromagnetic interference shielding tape is directly connected to the transparent conductive layer.

26. The display device according to claim 19, further comprising:
a flexible circuit film and a circuit substrate, the flexible circuit film being connected to the circuit substrate, and the source driver being connected to the flexible circuit film.

27. The display device according to claim 26, further comprising:
an electromagnetic interference shielding tape covering at least a portion of the flexible circuit film and the circuit substrate.

28. The display device according to claim 27, wherein
the circuit substrate includes a ground terminal, wherein
the electromagnetic interference shielding tape is connected to the ground terminal.

29. The display device according to claim 27, wherein
the electromagnetic interference shielding tape includes a metal film interposed between insulating films, and a portion of the electromagnetic interference shielding tape which is not covered by the insulating films is connected to the ground terminal.

30. The display device according to claim 22, wherein
the connecting member is a double-sided adhesive tape.

31. The display device according to claim 19, wherein
the first height adjusting body is compressible.

32. The display device according to claim 19, wherein
the first height adjusting body is electrically non-conductive.

33. The display device according to claim 19, wherein
the first height adjusting body is thermally conductive.

34. The display device according to claim 19, further comprising a liquid crystal layer disposed between the TFT substrate and the color filter substrate.
